(19) United States
(12) Patent Application Publication
(10) Pub. No.: US 2012/0328904 A1
(43) Pub. Date: Dec. 27, 2012

(54) PRINTED CIRCUIT BOARDS AND RELATED ARTICLES INCLUDING ELECTRODEPOSITED COATINGS

(75) Inventors: Donald M. Baskin, Sudbury, MA (US); John Cahalen, Somerville, MA (US); Jacob Sylvester, Gardner, MA (US)

(73) Assignee: Xtalic Corporation, Marlborough, MA (US)

(21) Appl. No.: 13/530,936

(22) Filed: Jun. 22, 2012

Related U.S. Application Data
(60) Provisional application No. 61/500,595, filed on Jun. 23, 2011.

(51) Int. Cl. B32B 33/00; C25D 7/00; H05K 1/09; C25D 5/02; C25D 15/00; B82Y 30/00

(52) U.S. Cl. 428/686; 205/125; 205/109; 174/257; 977/773

(57) ABSTRACT

Printed circuit boards and related articles including electrodeposited coatings are described herein.

### RELATED APPLICATIONS

This application claims priority to U.S. Provisional Patent Application Ser. No. 61/500,595, filed Jun. 23, 2011, which is incorporated herein by reference in its entirety.

### FIELD OF INVENTION

The present invention generally relates to articles, such as printed circuit boards, that include electrodeposited coatings, as well as electrodeposition processes for forming such coatings.

### BACKGROUND OF INVENTION

Many types of coatings may be applied on a base material. Electrodeposition is a common technique for depositing such coatings. Electrodeposition generally involves applying a voltage to a base material placed in an electrodeposition bath to reduce metal ionic species within the bath which deposit on the base material in the form of a metal, or metal alloy, coating. The voltage may be applied between an anode and a cathode using a power supply. At least one of the anode or cathode may serve as the base material to be coated. In some electrodeposition processes, the voltage may be applied as a complex waveform such as in pulse plating, alternating current plating, or reverse-pulse plating.

A variety of metal and metal alloy coatings may be deposited using electrodeposition. For example, metal alloy coatings can be based on two or more transition metals including Ni, W, Fe, Co, amongst others.

Corrosion processes, in general, can affect the structure and composition of an electroplated coating that is exposed to the corrosive environment. For example, corrosion can involve direct dissolution of atoms from the surface of the coating, a change in surface chemistry of the coating through selective dissolution or de-alloying, or a change in surface chemistry and structure of the coating through, e.g., oxidation or the formation of a passive film. Some of these processes may change the topography, texture, properties or appearance of the coating. For example, spotting and/or tarnishing of the coating may occur. Such effects may be undesirable, especially when the coating is applied at least in part to improve electrical conductivity since these effects can increase the resistance of the coating.

### SUMMARY OF INVENTION

Articles, such as printed circuit boards, that include electrodeposited coatings, as well as electrodeposition processes for forming such coatings are described herein.

In one aspect, a method of forming a conductive region on a printed circuit board structure is provided. The method comprises electrodepositing a first layer of a coating on a portion of a printed circuit board structure. The first layer comprises an alloy comprising nickel and tungsten. The weight percentage of tungsten in the first layer is between 10% and 35%. The first layer has a nanocrystalline grain size. The method further comprises electrodepositing a second layer of the coating formed over the first layer. The second layer comprises a precious metal. The second layer has a thickness of less than 35 microinches. The coating forms a conductive region on the printed circuit board structure.

In one aspect, a printed circuit board structure is provided. The structure comprises a conductive coating formed on a portion of the printed circuit board structure. The conductive coating includes a first layer comprising an alloy. The alloy comprises nickel and tungsten. The weight percentage of tungsten in the first layer is between 10% and 35%, and the first layer has a nanocrystalline grain size. The conductive coating includes a second layer formed over the first layer. The second layer comprises a precious metal and has a thickness of less than 35 microinches.

In one aspect, an article is provided. The article comprises a conductive coating formed on a base material. The conductive coating includes a first layer comprising an alloy. The alloy comprises nickel and tungsten. The weight percentage of tungsten in the first layer is between 10% and 35%. The first layer has a nanocrystalline grain size. The coating includes a second layer formed over the first layer. The second layer comprises a precious metal. The second layer has a nanocrystalline grain size and a thickness of less than 35 microinches. The surface of the conductive coating has a spotting area density of less than 0.1 after exposure to a neutral salt spray for 1 day according to ASTM B 117.

Other aspects, embodiments and features of the invention will become apparent from the following detailed description when considered in conjunction with the accompanying drawings. The accompanying figures are schematic and are not intended to be drawn to scale. For purposes of clarity, not every component is labeled in every figure, nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF THE DRAWINGS

FIGS. 1A and 1B respectively show coated articles according to some embodiments.

FIGS. 2A-2H show photographs of coated articles as described in Example 1.

FIG. 3 shows photographs of coated articles as described in Example 2.

### DETAILED DESCRIPTION

Articles and methods for applying coatings are described. The article may include a base material and a multi-layer coating formed thereon. In some cases, the coating includes a first layer that comprises an alloy (e.g., nickel-tungsten alloy) and a second layer that comprises a precious metal (e.g., Ru, Os, Rh, Ir, Pd, Pt, Ag, and/or Au). The coating may be applied using an electrodeposition process. The coating can exhibit desirable properties and characteristics such as durability, corrosion resistance, and high conductivity, which may be beneficial, for example, in electrical applications. For example, the article may be a printed circuit board which includes a portion upon which the coating is formed. In some cases, the presence of the first layer may allow for a reduction in the thickness of the second layer and, thus the amount of precious metal, while providing desirable properties.

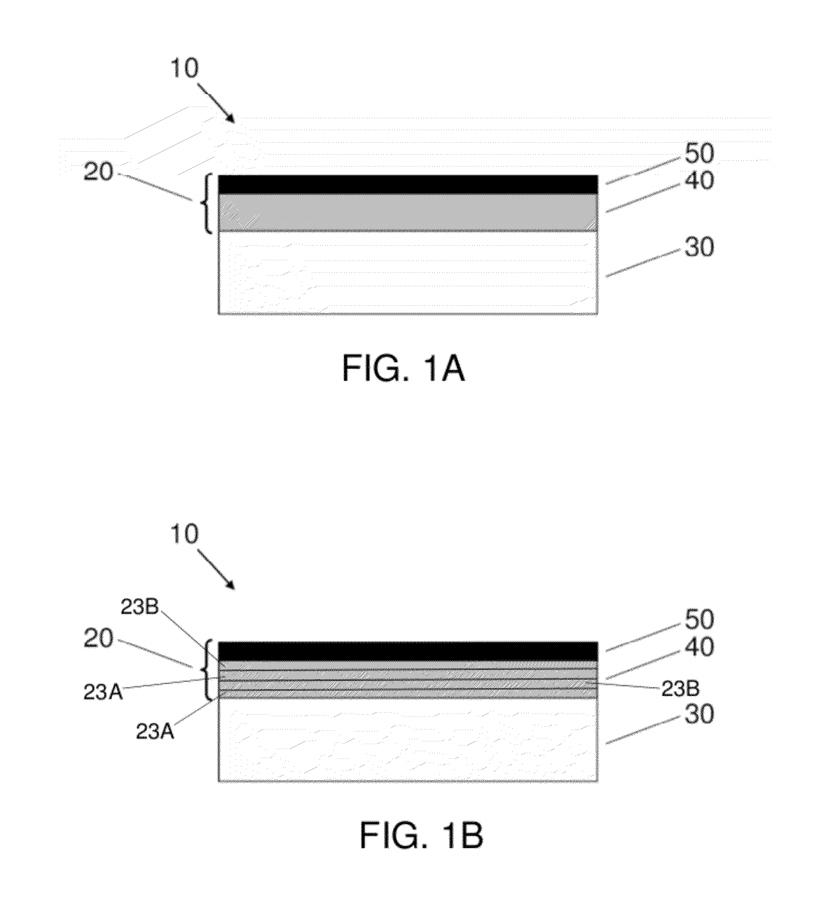

FIG. 1 shows a schematic representation of an article 10 according to an embodiment. The article has a coating 20 formed on a base material 30. The coating may comprise a first layer 40 formed on the base material and a second layer 50 formed on the first layer. Each layer may be applied using a suitable process, as described in more detail below. It should be understood that the coating may include more than two layers. However, in some embodiments, the coating may only include two layers, as shown.

In some embodiments, one of the layers (e.g., the first layer) comprises one or more metals. For example, such layer may comprise a metal alloy. In some cases, alloys that comprise nickel are preferred. In some cases, the alloy may comprise cobalt and/or iron. Cobalt and/or iron may be present in the alloy composition along with, or instead of, nickel. The alloys may also comprise tungsten and/or molybdenum. Nickel-tungsten alloys may be preferred in some cases.

In some cases, the total weight percentage of tungsten in the alloy is greater than or equal to 10 weight percent; in some cases, greater than or equal to 14 weight percent; in some cases, greater than or equal to 15 weight percent; and, in some cases greater than or equal to 20 weight percent. In some cases, the total weight percentage of tungsten in the alloy is less than or equal to 35 weight percent; in some cases, the total weight percentage of tungsten in the alloy is less than or equal to 30 weight percent; in some cases, the total weight percentage of tungsten in the alloy is less than or equal to 28 weight percent; and, the total weight percentage of tungsten in the alloy is less than or equal to 25 weight percent.

It should be understood that the total weight percentage of tungsten may be between any of the lower and upper weight percentages noted above. For example, in some cases, the total weight percentage of tungsten in the alloy may be between 10 weight percent and 35 weight percent; between 10 weight percent and 30 weight percent; between 10 weight percent and 28 weight percent; between 14 weight percent and 35 weight percent; between 14 weight percent and 30 weight percent; between 14 weight percent and 28 weight percent; in some cases, between 15 weight percent and 35 weight percent; between 15 weight percent and 30 weight percent; between 15 weight percent and 28 weight percent; and, in some cases, between 20 weight percent and 30 weight percent, and the like.

When the layer is a nickel-tungsten alloy, it should be understood that the weight percentage of nickel in the alloy equals 100% minus the weight percentage of tungsten. Therefore, for example, the weight percent of nickel in the alloy may be between 65 weight percent and 90 weight percent; between 70 weight percent and 90 weight percent; between 70 weight percent and 80 weight percent; between 65 weight percent and 85 weight percent, etc.

In some cases, the total atomic percentage of tungsten plus molybdenum in the alloy may be between 3.4 atomic percent and 14.7 atomic percent; and, the total atomic percentage of nickel may be between 85.3 atomic percent and 96.6 atomic percent.

The first layer may have any thickness suitable for a particular application. For example, the first layer thickness may be greater than about 4 microinch (e.g., between about 4 microinch and about 100 microinches, between about 4 microinch and 60 microinches); in some cases, greater than about 10 microinches (e.g., between about 10 microinches and about 60 microinches, between about 10 microinches and 100 microinches); and, in some cases, greater than about 25 microinches (e.g., between about 25 microinches and about 60 microinches, between about 25 microinch and 100 microinches).

The first layer thickness may be less than 100 microninches; in some cases, less than 75 microinches; in some cases, less than 60 microinches, and, in some cases, 50 mircoinches. It should be understood that other first layer thicknesses may also be suitable. In some embodiments, the thickness of the first layer is chosen such that the first layer is essentially transparent on the surface. Thickness may be measured by techniques known to those in the art.

In some embodiments, it may preferable for the first layer to be formed directly on the base material. Such embodiments may be preferred over certain prior art constructions that utilize a layer between the first layer and the base material because the absence of such an intervening layer can save on overall material costs. Though, it should be understood that in other embodiments, one or more layers may be formed between the first layer and the base material.

In some embodiments, it may be preferable for the first layer to include a plurality of sub-layers as shown in FIG. 1B. For example, the sub-layers may form a laminate structure. In some embodiments, the laminate structure includes an alternating series of one type of a sublayer 23A and a second type of a sublayer 23B. Sublayer 23A may be an alloy including an alloy comprising nickel, and tungsten and/or molybdenum (e.g., a nickel-tungsten alloy) as described above. In some cases, sublayer 23B may also be an alloy comprising nickel, and tungsten and/or molybdenum (e.g., a nickel-tungsten alloy), which can have a different composition than then alloy of sublayer 23A. For example, sublayer 23A may be an alloy that comprises tungsten between 10 weight percent and 35 weight percent, and nickel between 65 and 90 weight percent; and, in some embodiments, sublayer 23A may be an alloy that comprises tungsten between 20 weight percent and 30 weight percent, and nickel between 70 weight percent and 80 weight percent. Sublayer 23B may be an alloy that comprises tungsten between 25 weight percent and 45 weight percent, and nickel between 55 weight percent and 75 weight percent; in some embodiments, sublayer 23A may be an alloy that comprises tungsten between 30 weight percent and 40 weight percent, and nickel between 60 weight percent and 70 weight percent. The sublayers may have a thickness within any of the above-noted thickness ranges.

The first layer may cover an entire surface of the base material. However, it should be understood that in other embodiments, the first layer covers only part of a surface of the base material. In some cases, the first layer covers at least 50% of the area of a surface of the base material; and, in other cases, at least 75% of the area of a surface of the base material.

The second layer may comprise one or more precious metals. Examples of suitable precious metals include Ru, Os, Rh, Ir, Pd, Pt, Ag, and/or Au. Gold may be preferred in some embodiments. In some embodiments, the second layer consists essentially of one precious metal. In some embodiments, it may be preferable that the second layer is free of tin. In other cases, the second layer may comprise an alloy that includes at least one precious metal and at least one other metal. The metal may be selected from Ni, W, Fe, B, S, Co, Mo, Cu, Cr, Zn and Sn, amongst others.

The second layer may have any suitable thickness. It may be advantageous for the second layer to be thin, for example, to save on material costs. For example, the second layer thickness may be less than 35 microinches (e.g., between about 0.1 microinch and about 35 microinches; in some cases, between about 1 microinches and about 35 microinches); in some cases, less than 25 microinches (e.g., between about 0.1 microinch and about 25 microinches; in some cases, between about 1 microinches and about 25 microinches); in some cases, the second layer thickness may be less than 20 microinches (e.g., between about 0.1 microinch and about 20 microinches; in some cases, between about 5 microinches and about 20 microinches); and, in some cases, the second layer thickness may be less than 10 microinches (e.g., between about 0.1 microinch and about 10 microinches; in some cases, between about 1 microinches and about 10 microinches). In some embodiments, the thickness of the second layer is chosen such that the second layer is essentially transparent on the surface. It should be understood that other second layer thicknesses may also be suitable.

The second layer may cover the entire first layer. However, it should be understood that in other embodiments, the second layer covers only part of the first layer. For instance, the second layer may cover 10% or less of the surface area of the first layer. In some cases, the second layer covers at least 50% of the surface area of the first layer; in other cases, at least 75% of the surface area of the first layer. In some cases, an element from the first layer may be incorporated within the second layer and/or an element from the second layer may be incorporated into the first layer.

In some cases, the coating (e.g., the first layer and/or the second layer) may have a particular microstructure. For example, at least a portion of the coating may have a nanocrystalline microstructure. As used herein, a “nanocrystalline” structure refers to a structure in which the number-average size of crystalline grains is less than one micron. In some cases, the first layer and/or the second layer of the coating may have a number-average grain size of less than 100 nm; and, in some cases, less than 50 nm. The number-average size of the crystalline grains provides equal statistical weight to each grain and is calculated as the sum of all spherical equivalent grain diameters divided by the total number of grains in a representative volume of the body. In some embodiments, at least a portion of the coating may have an amorphous structure. As known in the art, an amorphous structure is a non-crystalline structure characterized by having no long range symmetry in the atomic positions. Examples of amorphous structures include glass, or glass-like structures. Some embodiments may provide coatings having a nanocrystalline structure throughout essentially the entire coating. Some embodiments may provide coatings having an amorphous structure throughout essentially the entire coating.

In some embodiments, the coating may comprise various portions having different microstructures. For example, the first layer may have a different microstructure than the second layer. The coating may include, for example, one or more portions having a nanocrystalline structure and one or more portions having an amorphous structure. In one set of embodiments, the coating comprises nanocrystalline grains and other portions which exhibit an amorphous structure. In some cases, the coating, or a portion thereof (i.e., a portion of the first layer, a portion of the second layer, or a portion of both the first layer and the second layer), may comprise a portion having crystal grains, a majority of which have a grain size greater than one micron in diameter. In some embodiments, the coating may include other structures or phases, alone or in combination with a nanocrystalline portion or an amorphous portion. Those of ordinary skill in the art would be able to select other structures or phases suitable for use in the context of the invention.

Advantageously, the coating (i.e., the first layer, the second layer, or both the first layer and the second layer) may be substantially free of elements or compounds having a high toxicity or other disadvantages. In some instances, it may also be advantageous for the coating to be substantially free of elements or compounds that are deposited using species that have a high toxicity or other disadvantages. For example, in some cases, the coating is free of chromium (e.g., chromium oxide), which is often deposited using chromium ionic species that are toxic (e.g., Cr⁶⁺). Such coating may provide various processing, health, and environmental advantages over certain previous coatings.

In some embodiments, metal, non-metal, and/or metalloid materials, salts, etc. (e.g., phosphate or a redox mediator such as potassium ferricyanide, or fragment thereof) may be incorporated into the coating.

The composition of the coatings, or portions or layers thereof, may be characterized using suitable techniques known in the art, such as Auger electron spectroscopy (AES), X-ray photoelectron spectroscopy (XPS), etc. For example, AES and/or XPS may be used to characterize the chemical composition of the surface of the coating.

Base material 30 may be coated to form coated articles, as described above. In some cases, the base material is a material suitable for use as a printed circuit board. For example, the material may be a dielectric material such as fiberglass, an epoxy resin, epoxy-glass weave, and PTFE. In the printed circuit board application, the dielectric material is typically coated with a conductive material such as an electrically conductive metal.

In some cases, the base material may comprise an electrically conductive material, such as a metal, metal alloy, intermetallic material, or the like. Suitable base materials include steel, copper, aluminum, brass, bronze, nickel, polymers with conductive surfaces and/or surface treatments, transparent conductive oxides, amongst others. In some embodiments, copper base materials are preferred.

As noted above, in some cases, the coated articles are printed circuit board structures. A printed circuit board, or PCB, can be used to mechanically support and electrically connect electronic components. For example, the coatings described herein may be formed on the printed circuit board's connectors (e.g., edge connectors) which have terminals (also referred to as “tabs” or “fingers”). In some cases, only the connector portions of the printed circuit boards are coated with the coatings described herein. In such cases, during the electrodeposition process, the other portions of the printed circuit boards may be covered, for example, with a mask material, while exposing the connector portions to be coated.

It should be understood that, as used herein, further examples of printed circuit board structures include smart cards, memory cards, thumb drives and the like. Such cards can be formed with embedded integrated circuits. The cards may be formed of plastic materials such as polyvinyl chloride, but sometimes acrylonitrile butadiene styrene or polycarbonate.

It should be understood that the coatings may be used in connection with other types of articles. In some embodiments, the coatings are formed on electrical connectors including plug-and-socket connectors. Suitable base materials and other electrical connector features have been described in commonly-owned U.S. Patent Publication No. 2011/0008646, based on application Ser. No. 12/500,786, filed Jul. 10, 2009, which is incorporated herein by reference in its entirety.

The coating can impart desirable characteristics to an article, such as durability, corrosion resistance, and improved electrical conductivity. In some embodiments, the presence of the first layer of a coating may provide at least some of the durability and corrosion resistance properties to the coating. Additionally, the presence of the first layer may allow the thickness of the second layer to be reduced, thereby reducing the amount of precious metal on the article significantly.

Coating 20 may be formed using an electrodeposition process. Electrodeposition generally involves the deposition of a material (e.g., electroplate) on a substrate by contacting the substrate with an electrodeposition bath and flowing electrical current between two electrodes through the electrodeposition bath, i.e., due to a difference in electrical potential between the two electrodes. For example, methods described herein may involve providing an anode, a cathode, an electrodeposition bath (also known as an electrodeposition fluid) associated with (e.g., in contact with) the anode and cathode, and a power supply connected to the anode and cathode. In some cases, the power supply may be driven to generate a waveform for producing a coating, as described more fully below.

Generally, the first layer and the second layer of the coating may be applied using separate electrodeposition baths. In some cases, individual articles may be connected such that they can be sequentially exposed to separate electrodeposition baths, for example in a reel-to-reel process. For instance, articles may be connected to a common conductive substrate (e.g., a strip). In some embodiments, each of the electrodeposition baths may be associated with separate anodes and the interconnected individual articles may be commonly connected to a cathode.

The electrodeposition process(es) may be modulated by varying the potential that is applied between the electrodes (e.g., potential control or voltage control), or by varying the current or current density that is allowed to flow (e.g., current or current density control). In some embodiments, the coating may be formed (e.g., electrodeposited) using direct current (DC) plating, pulsed current plating, reverse pulse current plating, or combinations thereof. In some embodiments, reverse pulse plating may be preferred, for example, to form the first layer (e.g., nickel-tungsten alloy). Pulses, oscillations, and/or other variations in voltage, potential, current, and/or current density, may also be incorporated during the electrodeposition process, as described more fully below. For example, pulses of controlled voltage may be alternated with pulses of controlled current or current density. In general, during an electrodeposition process an electrical potential may exist on the substrate (e.g., base material) to be coated, and changes in applied voltage, current, or current density may result in changes to the electrical potential on the substrate. In some cases, the electrodeposition process may include the use waveforms comprising one or more segments, wherein each segment involves a particular set of electrodeposition conditions (e.g., current density, current duration, electrodeposition bath temperature, etc.), as described more fully below.

In some embodiments, a coating, or portion thereof, may be electrodeposited using direct current (DC) plating. For example, a substrate (e.g., electrode) may be positioned in contact with (e.g., immersed within) an electrodeposition bath comprising one or more species to be deposited on the substrate. A constant, steady electrical current may be passed through the electrodeposition bath to produce a coating, or portion thereof, on the substrate. As described above, a reverse pulse current may also be used.

The electrodeposition processes use suitable electrodeposition baths. Such baths typically include species that may be deposited on a substrate (e.g., electrode) upon application of a current. For example, an electrodeposition bath comprising one or more metal species (e.g., metals, salts, other metal sources) may be used in the electrodeposition of a coating comprising a metal (e.g., an alloy). In some cases, the electrochemical bath comprises nickel species (e.g., nickel sulfate) and tungsten species (e.g., sodium tungstate) and may be useful in the formation of, for example, nickel-tungsten alloy coatings.

Typically, the electrodeposition baths comprise an aqueous fluid carrier (e.g., water). However, it should be understood that other fluid carriers may be used in the context of the invention, including, but not limited to, molten salts, cryogenic solvents, alcohol baths, and the like. Those of ordinary skill in the art would be able to select suitable fluid carriers for use in electrodeposition baths.

The electrodeposition baths may include other additives, such as wetting agents, brightening or leveling agents, and the like. Those of ordinary skill in the art would be able to select appropriate additives for use in a particular application. Some embodiments involve electrodeposition methods wherein the composition of the deposited alloy may be controlled by electrodeposition parameters (e.g., pulse parameters) and/or bath chemistry. Some embodiments involve electrodeposition methods wherein the grain size of the deposited alloy may be controlled by electrodeposition parameters (e.g., pulse parameters) and/or bath chemistry. In some embodiments, aspects of suitable methods and/or electrodeposition baths have been described in the following publications which are incorporated herein by reference in their entireties: U.S. Patent Publication No. 2006/02722949, entitled “Method for Producing Alloy Deposits and Controlling the Nanostructure Thereof using Negative Current Pulsing Electro-deposition, and Articles Incorporating Such Deposits”; U.S. Patent Publication No. 2009/0286103, based on application Ser. No. 12/120,564, entitled “Coated Articles and Related Methods,” filed May 14, 2008, U.S. Patent Publication No. 2010/0116675, based on application Ser. No. 12/266,979, filed Nov. 7, 2008, entitled “Electrodeposition Baths, Systems and Methods”.

The baths include suitable metal sources for depositing a coating with the desired composition. When depositing a metal alloy, it should be understood that all of the metal constituents in the alloy have sources in the bath. The metal sources are generally ionic species that are dissolved in the fluid carrier. As described further below, during the electrodeposition process, the ionic species are deposited in the form of a metal, or metal alloy, to form the coating. In general, any suitable ionic species can be used. The ionic species may be metal salts. For example, sodium tungstate, ammonium tungstate, tungstic acid, etc. may be used as the tungsten source when depositing a coating comprising tungsten; and, nickel sulfate, nickel hydroxy carbonate, nickel carbonate, nickel hydroxide, etc. may be used as the nickel source to deposit a coating comprising tungsten. In some cases, the ionic species may comprise molybdenum. It should be understood that these ionic species are provided as examples and that many other sources are possible.

As described herein, the electrodeposition baths may include one or more components (e.g., additives) that may enhance the performance of the baths in producing coated articles.

In some embodiments, the baths may include at least one brightening agent. The brightening agent may be any species that, when included in the baths described herein, improves the brightness and/or smoothness of the metal coating produced. In some cases, the brightening agent is a neutral species. In some cases, the brightening agent comprises a charged species (e.g., a positively charged ion, a negatively charged ion). In one set of embodiments, the brightening agent may comprise an alkyl group, optionally substituted. In some embodiments, the brightening agent may comprise a heteroalkyl group, optionally substituted.

In some cases, the brightening agent may be an alkynyl alkoxy alkane. For example, the brightening agent may comprise a compound having the following formula,

H—C≡C—[CH2]n-O—[R1],

wherein n is an integer between 1 and 100, and R1 is alkyl or heteroalkyl, optionally substituted. In some cases, the R1 is an alkyl group, optionally substituted with OH or SO3. In some embodiments, R1 comprises a group having the formula (R2)m, wherein R2 is alkyl or heteroalkyl, optionally substituted, and m is an integer between 3 and 103, such that n is less than or equal to (m−2). In some embodiments, n is an integer between 1 and 5. In some embodiments, m is an integer between 3 and 7. Some specific examples of brightening agents include, but are not limited to, propargyl-oxo-propane-2,3-dihydroxy (POPDH) and propargyl-3-sulfopropyl ether Na salt (POPS). It should be understood that other alkynyl alkoxy alkanes may also be useful as brightening agents.

In some cases, the brightening agent may comprise an alkyne. For example, the alkyne may be a hydroxy alkyne. In some embodiments, the brightening agent may comprise a compound having the following formula,

[R3]x—C≡C—[R4]y,

wherein R3 and R4 can be the same or different and each is H, alkyl, hydroxyalkyl, or amino optionally substituted, and x and y can the be same or different and each is an integer between 1 and 100. In some cases, at least one of R3 or R4 comprises a hydroxyalkyl group. In some instances, at least one of R3 or R4 comprises an amino functional group. In some embodiments, x and y can be the same or different and are integers between 1-5, and at least one of R3 and R4 comprises a hydroxyalkyl group. In an illustrative embodiment, the alkyne is 2-butyne-1,4-diol. In another illustrative embodiment, the alkyne is 1-diethylamino-2-propyne. It should be understood that other alkynes may also be useful as brightening agents within the context of the invention. In some cases, the brightening agent may be chosen from those molecules falling within the betain family, where a betain is a neutrally charged compound comprised of a positively charged cationic functional group and a negatively charged anionic functional group. Here examples of the cationic side of the betain could be ammonium, phosphonium, or pyridinium groups optionally substituted, and examples of the anionic side could be carboxylic, sulfonic, or sulfate groups. It should be understood that these functional groups are for illustration and are not intended to be limiting.

In some cases, the electrodeposition baths may include a combination of at least two brightening agents. For example, a bath may comprise both a brightening agent comprising an alkynyl alkoxy alkane and a second brightening agent comprising an alkyne.

The baths may comprise the brightening agent in a concentration of from 0.05 g/L to 5 g/L, from 0.05 g/L to 3 g/L, from 0.05 g/L to 1 g/L, or, in some cases, from 0.01 g/L to 1 g/L. In some cases, the baths may comprise the brightening agent in a concentration of from 0.05 g/L to 1 g/L, from 0.05 g/L to 0.50 g/L, from 0.05 g/L to 0.25 g/L, or, in some cases, from 0.05 g/L to 0.15 g/L. Those of ordinary skill in the art would be able to select the concentration of brightening agent, or mixture of brightening agents, suitable for use in a particular application.

Those of ordinary skill in the art would be able to select the appropriate brightening agent, or combination of brightening agents, suitable for use in a particular invention. In some embodiments, the alkynyl alkoxy alkane, alkyne, or other brightening agent may be selected to exhibit compatibility (e.g., solubility) with the eletroplating bath and components thereof. For example, the brightening agent may be selected to include one or more hydrophilic species to provide greater hydrophilicity to the brightening agent. The hydrophilic species can be, for example, amines, thiols, alcohols, carboxylic acids and carboxylates, sulfates, phosphates, polyethylene glycols (PEGs), or derivatives of polyethylene glycol. The presence of a hydrophilic species can impart enhanced water solubility to the brightening agent. For example, R1, R2, and/or R3 as described above may be selected to comprise a hydroxyl group or a sulfate group. In some cases, the baths may include at least one wetting agent. A wetting agent refers to any species capable of increasing the wetting ability of the electrodeposition bath with the surface of the article to be coated. For example, the substrate may comprise a hydrophilic surface, and the wetting agent may enhance the compatibility (e.g., wettability) of the bath relative to the substrate. In some cases, the wetting agent may also reduce the number of defects within the metal coating that is produced. The wetting agent may comprise an organic species, an inorganic species, an organometallic species, or combinations thereof. In some embodiments, the wetting agent may be selected to exhibit compatibility (e.g., solubility) with the eletroplating bath and components thereof. For example, the wetting agent may be selected to include one or more hydrophilic species, including amines, thiols, alcohols, carboxylic acids and carboxylates, sulfates, phosphates, polyethylene glycols (PEGs), or derivatives of polyethylene glycol, to enhance the water solubility of the wetting agent. In one set of embodiments, the wetting agent may comprise an aromatic group, optionally substituted. For example, the wetting agent may comprise a naphthyl group substituted with one or more an alkyl or heteroalkyl group, optionally substituted.

Additives described herein can be used both individually and/or in any combinations thereof to provide improved coating quality through brightening, leveling and reduction in propensity for surface pitting.

In some embodiments, the electrodeposition bath may include additional additives. For example, the electrodeposition bath may comprise one or more complexing agents. A complexing agent refers to any species which can coordinate with the metallic ions contained in the solution. The complexing agent may be an organic species, such as a citrate ion, or an inorganic species, such as an ammonium ion. In some cases, the complexing agent is a neutral species. In some cases, the complexing agent is a charged species (e.g., negatively charged ion, positively charged ion). Examples of complexing agents include citrates, gluconates, tartrates, and other alkyl hydroxyl carboxylic acids. Generally, a complexing agent, or mixture of complexing agents, may be included in the electrodeposition bath within a concentration range of 10-200 g/L, and, in some cases, within the range of 40-80 g/L. In one embodiment, the complexing agent is a citrate ion. In some embodiments, ammonium ions may be incorporated into the electrolyte bath as complexing agents and to adjust solution pH. For example, the electrodeposition bath may comprise ammonium ions in the range of 1-50 g/L, and between 10-30 g/L.

Methods of the invention may be advantageous in that coatings (e.g., Ni—W alloy coatings) having various compositions may be readily produced by a single electrodeposition step. For example, a coating comprising a layered composition, graded composition, etc., may be produced in a single electrodeposition bath and in a single deposition step by selecting a waveform having the appropriate segments. The coated articles may exhibit enhanced corrosion resistance and surface properties.

It should be understood that other techniques may be used to produce coatings as described herein, including vapor-phase processes, sputtering, physical vapor deposition, chemical vapor deposition, thermal oxidation, ion implantation, spray coating, powder-based processes, slurry-based processes, etc.

In some embodiments, the invention provides coated articles that are capable of resisting corrosion, and/or protecting an underlying substrate material from corrosion, in one or more potential corrosive environments. Examples of such corrosive environments include, but are not limited to, aqueous solutions, acid solutions, alkaline or basic solutions, or combinations thereof. For example, coated articles described herein may be resistant to corrosion upon exposure to (e.g., contact with, immersion within, etc.) a corrosive environment, such as a corrosive liquid, vapor, or humid environment.

The corrosion resistance may be assessed using test standards such as ASTM B117 (Neutral Salt Spray); JEDEC 205 (Damp Heat); ASTM B735 (Nitric Acid); and IEC 68-2-60 (e.g., Method 4) (Mixed Flowing Gas). These tests outline procedures in which coated substrate samples are exposed to a corrosive atmosphere (i.e., neutral salt spray, damp heat, nitric acid vapor or a mixture of NO₂, H₂S, Cl₂, and SO₂).

The exposure time of an article to a gas or gas mixture can be variable, and is generally specified by the end user of the product or coating being tested. For example, the exposure time may be 30 minutes, 2 hours, 1 day, 5 days, or 40 days, amongst other times. After a prescribed amount of exposure time, the sample is examined (e.g., visually by human eye and/or instrumentally as described below) for signs of change to the surface appearance and/or electrical conductivity resulting from corrosion and/or spotting. The test results can be reported using a simple pass/fail approach after the exposure time.

The coating subjected to the test conditions discussed above may be evaluated, for example, by measuring the change in the appearance of the coating. For instance, a critical surface area fraction may be specified, along with a specified time. If, after testing for the specified time, the fraction of the surface area of the coating that changes in appearance resulting from corrosion is below the specified critical value, the result is considered passing. If more than the critical fraction of surface area has changed in appearance resulting from corrosion, then the result is considered failing. For example, the extent of corrosive spotting may be determined. The extent of spotting may be quantified by determining the number density and/or area density of spots after a specified time. For example, the number density may be determined counting the number of spots per unit area (e.g., spots/cm²). The spot area density can be evaluated by measuring the fraction of the surface area occupied by the spots, where, for example, a spot area density equal to 1.0 indicates that 100% of the surface area is spotted, a spot area density equal to 0.5 indicates that 50% of the surface area is spotted, a spot area density equal to 0.1 indicates that 10% of the surface area is spotted and a spot area density equal to 0 indicates that none of the surface area is spotted.

In some cases, after exposure to nitric acid vapor according to ASTM B735, the article has a spot area density of less than 0.10; in some cases, less than 0.05; and, in some cases, 0. In some embodiments, these spot area densities may be achieved when the exposure time is 30 minutes, 2 hours, 1 day, 5 days or 40 days. In some embodiments, the coated article exposed to these conditions has a number density of spots of less than 3 spots/cm²; in some embodiments, less than 2 spots/cm²; and, in some embodiments, 0 spots/cm². It should be understood that spot area densities and the number density of spots may be outside the above-noted ranges.

In some cases, after exposure to neutral salt spray according to ASTM B117, the article has a spot area density of less than 0.10; in some cases, less than 0.05; and, in some cases, 0. In some embodiments, these spot area densities may be achieved when the exposure time is 30 minutes, 2 hours, 1 day, 5 days or 40 days. In some embodiments, the coated article exposed to these conditions has a number density of spots of less than 3 spots/cm²; in some embodiments, less than 2 spots/cm²; and, in some embodiments, 0 spots/cm². It should be understood that spot area densities and the number density of spots may be outside the above-noted ranges.

In some cases, after exposure to damp heat according to JEDEC 205, the article has a spot area density of less than 0.10; in some cases, less than 0.05; and, in some cases, 0. In some embodiments, these spot area densities may be achieved when the exposure time is 15 minutes, 30 minutes, 2 hours, 1 day, 5 days or 40 days. In some embodiments, the coated article exposed to these conditions has a number density of spots of less than 3 spots/cm²; in some embodiments, less than 2 spots/cm²; and, in some embodiments, 0 spots/cm². It should be understood that spot area densities and the number density of spots may be outside the above-noted ranges.

In some cases, after exposure to mixed flowing glass according to IEC 68-2-60 (e.g., Method 4), the article has a spot area density of less than 0.10; in some cases, less than 0.05; and, in some cases, 0. In some embodiments, these spot area densities may be achieved when the exposure time is 30 minutes, 2 hours, 1 day, 5 days or 40 days. In some embodiments, the coated article exposed to these conditions has a number density of spots of less than 3 spots/cm²; in some embodiments, less than 2 spots/cm²; and, in some embodiments, 0 spots/cm². It should be understood that spot area densities and the number density of spots may be outside the above-noted ranges.

In some cases, advantageously, the articles exhibit excellent corrosion resistance as measured by all four of the above-described test standards.

The following example should not be considered to be limiting but illustrative of certain features of the invention.

### Example 1

This example compares the corrosion resistance of an article including a coating having a first layer produced in accordance with some embodiments of the invention to the corrosion resistance of an articles having conventional coatings (nickel sulfamate coatings).

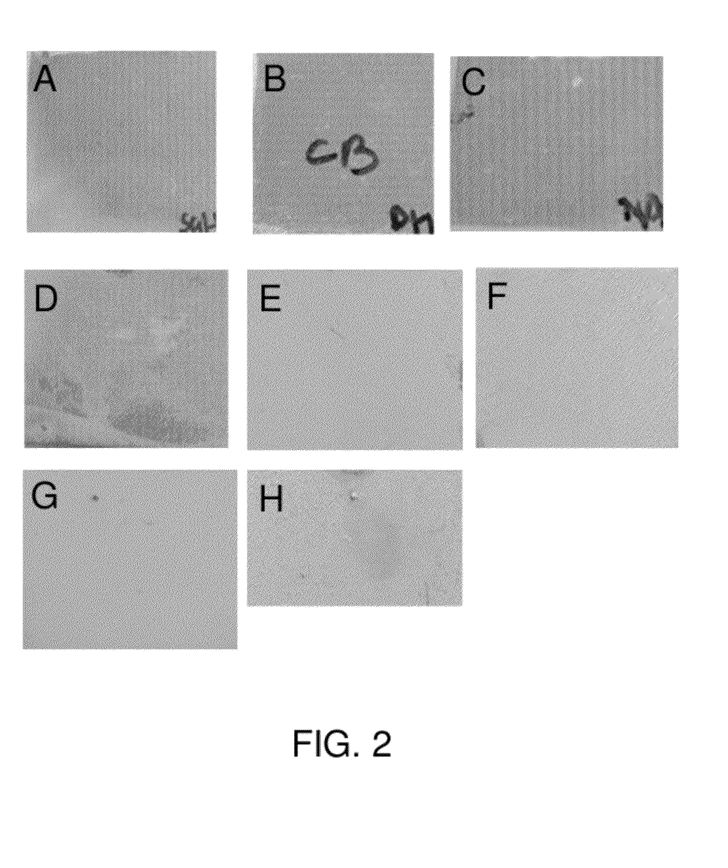

FIGS. 2A, 2C, 2E, and 2G respectively show coated articles, similar to the one shown in FIG. 1, after corrosion tests (ASTM B117; JEDEC 205; ASTM B735; IEC 68-2-60, Method 4). For these articles, the substrate is formed of a copper-clad fiberglass; the first layer has a thickness of 40-60 micro-inches and is formed of a nickel-tungsten alloy which includes a weight percentage of tungsten between 20-30% and a weight percentage of nickel between 70-80%; and, the second layer has a thickness of about 10 micro-inches and is formed of a gold alloy. The first layer was formed using an electrodeposition process that involved a pulsed reverse waveform. The second layer was formed using an electrodeposition process that involved a direct current waveform.

FIGS. 2B, 2D, 2F, and 2H respectively show coated articles which include conventional coatings after the same corrosion tests noted above (ASTM B117; JEDEC 205; ASTM B735; IEC 68-2-60, Method 4). For these articles, the substrate is formed of a copper-based material; the first layer has a thickness of about 200 micro-inches and is formed of nickel sulfamate; and, the second layer has a thickness of about 30 micro-inches and is formed of a gold alloy. The first and second layers were formed using an electrodeposition process that involved a direct current waveform.

The testing of the coated articles shown in FIGS. 2A and 2B involved exposure to an aqueous sodium chloride solution (neutral salt spray) for 1 day according to testing standard ASTM B 117.

The testing of the coated articles shown in FIGS. 2C and 2D involved exposure to a highly humid environment (ca. 95 relative humidity) at high temperature (90° C.) for 1 day according to testing standard JEDEC 205.

The testing of the coated articles shown in FIGS. 2E and 2F involved exposure to nitric acid for 75 minutes according to testing standard ASTM B735.

The testing of the coated articles shown in FIGS. 2G and 2H involved exposure to mixed flowing gas for 5 days according to testing standard IEC 68-2-60, Method 4.

FIGS. 2A and 2B show essentially no corrosion.

FIG. 2C shows essentially no corrosion. FIG. 2D shows a low level of corrosion.

FIG. 2E shows essentially no corrosion. FIG. 2F shows a low level of corrosion.

FIG. 2G shows a low level of corrosion. FIG. 2H shows a low level of corrosion.

The results of the testing show that the corrosion resistance of articles including a coating having a first layer produced in accordance with some embodiments of the invention are similar or better than the corrosion resistance of articles having conventional coating compositions (i.e., nickel sulfamate coatings). It is noteworthy that these results are achievable with the articles including a coating having a first layer produced in accordance with some embodiments of the invention when using significantly lower amounts of gold (e.g., about 33% as much gold) than used in the conventional coated articles. Therefore, the same, or better, performance can be achieved with significantly lower material costs.

### Example 2

This example compares the corrosion resistance of articles including a coating having a first layer formed of nickel-tungsten with varying weight percentages of nickel and tungsten.

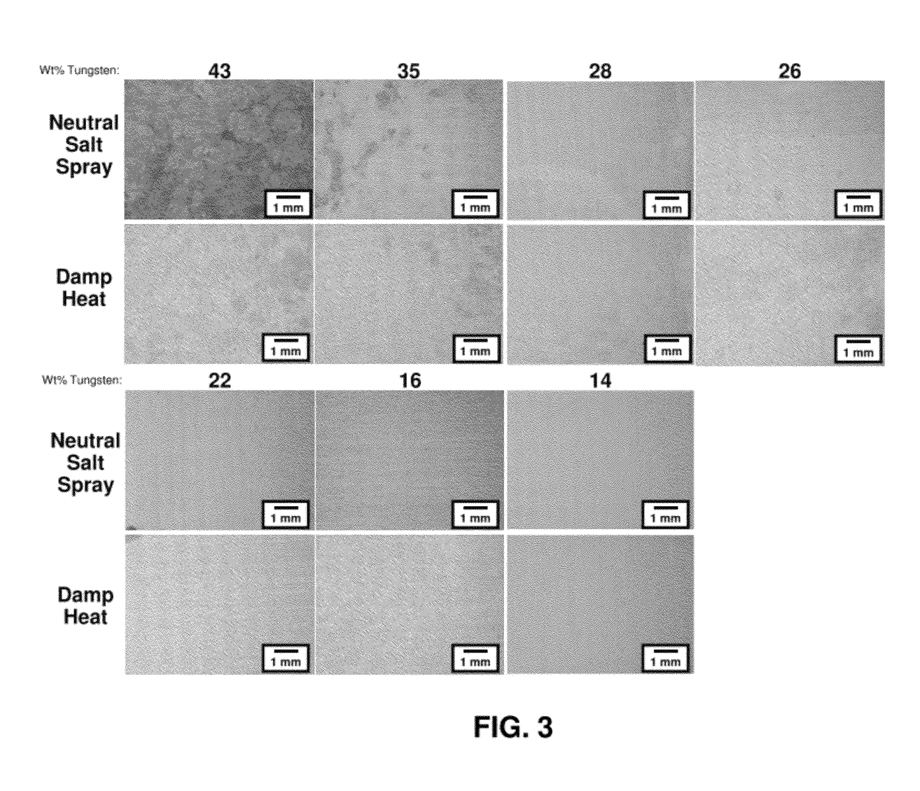

FIG. 3. shows photographs of coated articles after a neutral salt spray test according to ASTM B117 with an exposure time of 1 day, and a damp heat test (ca. 95 relative humidity, 90° C. temperature) according to JEDEC 205 with an exposure time of 1 day.

For these articles, the substrate is formed of a copper-clad fiberglass; the first layer has a thickness of 40-60 micro-inches and is formed of a nickel-tungsten alloy having a varying weight percentage of tungsten and nickel; the second layer has a thickness of about 10 micro-inches and is formed of a gold alloy. As shown on the figures, the articles that were tested included 43% W/57% Ni; 35% W/65% Ni; 28% W/72% Ni; 26% W/74% Ni; 22% W/78% Ni; 16% W/84% Ni; and, 14% W/86% Ni. The first layer was formed using an electrodeposition process that involved a pulsed reverse waveform. The second layer was formed using an electrodeposition process that involved a direct current waveform.

The articles show essentially no corrosion (a spot density of 0) following both tests when the first layer has less than 35% tungsten. At 35% tungsten, the articles show a low level of corrosion following the damp heat test and slightly more corrosion following the neutral salt spray. At 43% tungsten, the articles show more corrosion following both tests than at 35% tungsten.

What is claimed is:

1. A method of forming a conductive region on a printed circuit board structure comprising:
electrodepositing a first layer of a coating on a portion of a printed circuit board structure, wherein the first layer comprises an alloy comprising nickel and tungsten, wherein the weight percentage of tungsten in the first layer is between 10% and 35%, and wherein the first layer has a nanocrystalline grain size; and
electrodepositing a second layer of the coating formed over the first layer, the second layer comprising a precious metal, wherein the second layer has a thickness of less than 35 microinches,
wherein the coating forms a conductive region on the printed circuit board structure.

2. The method of claim 1, wherein the weight percentage of tungsten in the first layer is between 15% and 30%.

3. The method of claim 1, wherein the first layer is electrodeposited using a reverse pulse process.

4. The method of claim 1, wherein the precious metal is gold.

5. The method of claim 1, wherein the thickness is less than 25 microinches.

6. The method of claim 1, wherein the second layer has a nanocrystalline grain size.

7. The method of claim 1, wherein the first layer has an average grain size of less than 100 nm.

8. The method of claim 1, wherein the printed circuit board structure is a smart card.

9. The method of claim 1, wherein the printed circuit board structure is a flash memory card.

10. The method of claim 1, wherein the portion of the printed circuit board structure that is coated comprises a connector.

11. A printed circuit board structure comprising:
a conductive coating formed on a portion of the printed circuit board structure, the conductive coating including:
a first layer comprising an alloy, the alloy comprises nickel and tungsten, wherein the weight percentage of tungsten in the first layer is between 10% and 35%, and wherein the first layer has a nanocrystalline grain size; and
a second layer formed over the first layer, the second layer comprising a precious metal, wherein the second layer has a thickness of less than 35 microinches.

12. The printed circuit board structure of claim 11, wherein the weight percentage of tungsten in the first layer is between 15% and 30%.

13. The printed circuit board structure of claim 11, wherein the precious metal is gold.

14. The printed circuit board structure of claim 11, wherein the thickness is less than 25 microinches.

15. The printed circuit board structure of claim 11, wherein the second layer has a nanocrystalline grain size.

16. The printed circuit board structure of claim 11, wherein the first layer has an average grain size of less than 100 nm.

17. The printed circuit board structure of claim 11, wherein the printed circuit board structure is a smart card.

18. The printed circuit board structure of claim 11, wherein the printed circuit board structure is a flash memory card.

19. The printed circuit board structure of claim 11, wherein the portion of the printed circuit board structure that is coated comprises a connector.

20. An article comprising:
a conductive coating formed on a base material, the conductive coating including:
a first layer comprising an alloy, the alloy comprises nickel and tungsten, wherein the weight percentage of tungsten in the first layer is between 10% and 35%, and wherein the first layer has a nanocrystalline grain size; and
a second layer formed over the first layer, the second layer comprising a precious metal, wherein the second layer has a nanocrystalline grain size and a thickness of less than 35 microinches; and
wherein a surface of the conductive coating has a spot area density of less than 0.1 after exposure to a neutral saltspray for 1 day according to ASTM B117.

21. The article of claim 20, wherein the weight percentage of tungsten in the first layer is between 15% and 30%.

22. The article of claim 20, wherein the precious metal is gold.

23. The article of claim 20, wherein the thickness is less than 25 microinches.

24. The article of claim 20, wherein the second layer has a nanocrystalline grain size.

25. The article of claim 20, wherein the first layer has an average grain size of less than 100 nm.
